(19) United States
(12) Patent Application Publication
(10) Pub. No.: US 2023/0072156 A1
(43) Pub. Date: Mar. 9, 2023

(54) SUBSTRATE PROCESSING APPARATUS

(71) Applicant: WONIK IPS CO., LTD., Pyeongtaek-si Gyeonggi-do (KR)

(72) Inventors: Sung Ho ROH, Yongin-si Gyeonggi-do (KR); Jung Hwan LEE, Osan-si Gyeonggi-do (KR); Cheong Hwan JEONG, Anseong-si Gyeonggi-do (KR); Tae Dong KIM, Osan-si Gyeonggi-do (KR); Young Jun KIM, Pyeongtaek-si Gyeonggi-do (KR); Moon Chul KUM, Gwangmyeong-si Gyeonggi-do (KR); Chan Soo PARK, Osan-si Gyeonggi-do (KR); Mi Sook KIM, Yongin-si Gyeonggi-do (KR); Yong Ki KIM, Hwaseong-si Gyeonggi-do (KR)

(73) Assignee: WONIK IPS CO., LTD., Pyeongtaek-si Gyeonggi-do (KR)

(21) Appl. No.: 17/901,562

(22) Filed: Sep. 1, 2022

(30) Foreign Application Priority Data
Sep. 2, 2021 (KR) 10-2021-0117027
Sep. 2, 2021 (KR) 10-2021-0117029
Sep. 15, 2021 (KR) 10-2021-0123220
Aug. 11, 2022 (KR) 10-2022-0100376

(51) Int. Cl. H01L 21/67; H01L 21/673; H01L 21/677

(52) U.S. Cl. CPC H01L 21/67017; H01L 21/67393; H01L 21/67742

(57) ABSTRACT

The present invention disclosed herein relates to a substrate processing apparatus, and more particularly, to a substrate processing apparatus that performs substrate processing through a pressure change between a high pressure and a low pressure. The present invention discloses a substrate processing apparatus including; a process chamber (100) comprising a chamber body (110) which has an opened upper portion, in which an installation groove (130) is defined at a central side of a bottom surface (120) thereof, and which comprises a gate (111) for loading/unloading a substrate (1) is disposed at one side thereof and a top lid (140) coupled to the upper portion of the chamber body (110) to define an inner space, a substrate support (200) installed to be inserted into the installation groove (130) of the chamber body (110) and having a top surface on which the substrate (1) is seated.

### CROSS-REFERENCE TO RELATED APPLICATIONS

This U.S. non-provisional patent application claims priority under 35 U.S.C. § 119(a) to Korean Patent Application No. 10-2021-0117027, filed on Sep. 2, 2021, Korean Patent Application No. 10-2021-0117029, filed on Sep. 2, 2021, Korean Patent Application No. 10-2021-0123220, filed on Sep. 15, 2021, and Korean Patent Application No. 10-2022-0100376, filed on Aug. 11, 2022, in the Korean Intellectual Property Office, the entire contents of which are hereby incorporated by reference.

### FIELD OF THE INVENTION

The present invention disclosed herein relates to a substrate processing apparatus, and more particularly, to a substrate processing apparatus that performs substrate processing through a pressure change between a high pressure and a low pressure.

### BACKGROUND ART

The substrate processing apparatus may perform a process of processing a substrate such as a wafer, in general, perform etching, deposition, heat treatment, and the like on the substrate.

Here, when a film is formed on the substrate through the deposition, a process of removing impurities within the film and improving characteristics of the film after forming the thin film on the substrate is being required.

Particularly, as 3D semiconductor devices and substrates having a high aspect ratio appear, since a deposition temperature is lowered to meet a step coverage standard, or a gas having a high impurity content is inevitably used, the removing of the impurities within the film is becoming more difficult.

Accordingly, there is a need for a substrate processing method, which is capable of improving the characteristics of the thin film by removing the impurities existing in the thin film without deterioration in characteristics of the thin film after forming the thin film on the substrate, and an apparatus for processing the substrate, which performs the method.

In addition, there is a limitation that the deposited thin film is contaminated by a small amount of impurities, which remain in a chamber as well as the thin film on the substrate, and thus, it is necessary to remove the impurities from the inside of the chamber including a substrate support that supports the substrate.

To improve this limitation, Korean Patent Application No. 10-2021-0045294A, which is the related art, disclosures a substrate processing method, in which high-pressure and low-pressure atmospheres are repeatedly formed to reduce imperfection on a surface of a substrate and the inside of a chamber, thereby improving characteristics of a thin film.

However, when the above-described substrate processing method is applied to the substrate processing apparatus according to the related art, since a volume of a processing space for processing a substrate is relatively large to cause a limitation that it is difficult to realize a fast pressure change rate.

In addition, the substrate processing apparatus according to the related art has a limitation in that it is difficult to implement a process of repeatedly performing a wide pressure range from a low pressure of about 0.01 Tons to a high pressure of about 5 Bars within a short time.

To solve this limitation, a volume of the processing space may be minimized in the substrate processing apparatus according to the related art, but there is a limitation in that a dead volume still increases due to a configuration of the gas supply part for supplying a process gas into the processing space.

In addition, since the gas supply part has to be separately installed while minimizing the volume in the limited processing space, the gas supply part may be disposed at a position adjacent to the substrate support. Thus, the process gas may be supplied from an edge of the substrate to a center of the substrate, and thus, there is a limitation in that uniform substrate processing is not performed because the process gas is not transferred.

Particularly, in the substrate processing apparatus according to the related art, a pumping passage for exhausting the processing space is provided between the substrate support and the gas supply part, and thus, there is a limitation that the process gas is not transferred to the center of the substrate.

In addition, as the substrate processing apparatus according to the related art performs substrate processing through a repeated pressure change between high and low pressures, it is easy to damage sealing for the sealed processing space, and thus, the process gas therein leaks under a high pressure environment, or external impurities is easily introduced under a low pressure environment.

In this case, there is a limitation that harmful substances such as the process gas leaks out of the process chamber.

In addition, the substrate processing apparatus according to the related art has a limitation in that the exhaust of the processing space, in which a pressure is repeatedly changed from a high pressure to a low pressure, is performed in a simple line, and thus, an external vacuum pump connected to the outside is exposed to be damaged, thereby deteriorating durability.

### SUMMARY OF THE INVENTION

To solve the above limitations, an object of the present invention is to provide a substrate processing apparatus which is capable of preventing impurities from being introduced and preventing a process gas from leaking to the outside to improve quality and safety.

In accordance with an embodiment of the present invention, a substrate processing apparatus includes: a process chamber 100 including a chamber body 110 which has an opened upper portion, in which an installation groove 130 is defined at a central side of a bottom surface 120 thereof, and which includes a gate 111 configured to load/unload a substrate 1 is disposed at one side thereof, and a top lid 140 coupled to the upper portion of the chamber body 110 to define an inner space; a substrate support 200 installed to be inserted into the installation groove 130 of the chamber body 110 and having a top surface on which the substrate 1 is seated; an inner lid part 300 which is installed to be vertically movable in the inner space and of which a portion is in close contact with the bottom surface 120 adjacent to the installation groove 130 through descending to divide the inner space into a sealed processing space S2 in which the substrate support 200 is disposed and other non-processing space S1; a first pressure adjusting part 400 communicating with the processing space S2 to adjust a pressure of the processing space S2; a second pressure adjusting part 500 communicating with the non-processing space S1 to adjust a pressure of the non-processing space S1 independently of the processing space S2; and a controller configured to control the pressure adjusting of the processing space S2 and the non-processing space S1 through the first pressure adjusting part 400 and the second pressure adjusting part 500.

The first pressure adjusting part 400 may include a first gas supply part 410 configured to supply the process gas to the processing space S2 and a first gas exhaust part 420 configured to exhaust the processing space S2.

The second pressure adjusting part 500 may include a second gas exhaust part 520 connected to a gas exhaust hole 180 defined at one side of the process chamber 100 to exhaust the non-processing space S1.

The second pressure adjusting part 500 may include a second gas supply part 510 connected to a gas supply hole 170 defined at the other side of the process chamber 100 so as to communicate with the non-processing space S1 and supply a filling gas to the non-processing space S1.

The second pressure adjusting part 500 may include a second gas exhaust part configured to exhaust the non-processing space S1 and a second gas supply part communicating with the non-processing space S1 to transfer the filling gas to the non-processing space S1, wherein the second gas supply part may include a gas supply hole 170 defined in one surface of the process chamber 100, and the second gas exhaust part may include a gas exhaust hole 180 defined in the other surface of the process chamber 100.

The controller may supply a purge gas through the first gas supply part 410 to supply the purge gas through the first gas supply part 410 and exhaust the purge gas through the second gas exhaust part 520 in a state in which the inner lid part 300 ascends to allow the processing space Si and the non-processing space S1 to communicate with each other.

The controller may control, before the inner lid part 300 ascends, at least one of the first pressure adjusting part 400 or the second pressure adjusting part 500 so that the pressures of the processing space S2 and the non-processing space S1 are the same.

The controller may change the pressure of the processing space S1, in which the substrate 1 is seated to perform the substrate processing, between a first pressure higher than a normal pressure and a second pressure lower than the normal pressure through the first pressure adjusting part 400.

The controller may constantly maintain the pressure in the non-processing space S1 while the substrate processing is performed through the second pressure adjusting part 500.

The controller may maintain the pressure in the non-processing space S1 to a vacuum pressure while the substrate processing is performed through the second pressure adjusting part 500.

The second pressure adjusting part 500 may adjust the pressure of the non-processing space S3 through only the exhaust the non-processing space S1 through the second pressure adjusting part 500.

The controller may supply a filling gas to the non-processing space S 1 through the second pressure adjusting part 500 to adjust the pressure of the non-processing space S1.

The controller may maintain the pressure in the non-processing space Si to a pressure lower than the pressure in the processing space S2 while the substrate processing is performed through the second pressure adjusting part 500.

The controller may maintain the pressure of the non-processing space S1 to the second pressure while the substrate processing is performed through the second pressure adjusting part 500.

The controller may fall the pressure of the processing space S2 from the first pressure to the normal pressure through the first pressure adjusting part 400 and fall the pressure of the processing space S2 side by side from the normal pressure to the second pressure that is in a vacuum pressure.

The controller may sequentially and repeatedly change the pressure of the processing space S2 several times from the first pressure to the second pressure and then to first pressure through the first pressure adjusting part 400 so as to perform the substrate processing.

The first pressure adjusting part 400 may include a first gas supply part 410 installed to communicate with the processing space S2 to supply the process gas to the processing space S2 and installed adjacent to an edge of the substrate support 200.

The first pressure adjusting part 400 may include a first gas supply part 410 installed to communicate with the processing space S2 so as to supply the process gas to the processing space S2, and the first gas supply part 410 may include a gas injection part 416 installed on the edge of the installation groove 130 to inject the process gas, and a gas supply passage 417 provided to pass through a bottom surface of the process chamber 100 to supply the process gas to the gas injection part 416 from the outside.

The inner lid part 300 may include an inner lid 310 that moves vertically in the inner space, and a gas supply passage 320 provided to communicate with the processing space S2 inside the inner lid 310.

The substrate processing apparatus may further include a first gas supply part 410 disposed under the inner lid part 300 to inject the process gas transferred through the gas supply passage 320 to the processing space S2.

The first gas supply part 410 may include an injection plate 412 disposed under the inner lid part 300 and provided with a plurality of injection holes 411.

The first gas supply part 410 may include an injection plate support 413 that supports an edge of the injection plate 412 and is coupled to a bottom surface of the inner lid part 300.

The first gas supply part 410 may further include a plurality of coupling members 414 passing through the injection plate support 413 and coupled to the inner lid part 300.

The injection plate 412 may be disposed to be spaced downward from the inner lid part 300 to define a diffusion space S3 in which the process gas is diffused between the injection plate 412 and the inner lid part 300.

The injection plate 412 may be made of a metal or quartz material.

The injection plate support 413 may protrude toward a center on an inner surface and may include a support stepped part 415 on which an edge of a bottom surface of the injection plate 412 is seated.

The inner lid 310 may include an insertion installation groove 330 in which at least a portion of the first gas supply part 410 is inserted and installed on the bottom surface thereof.

The insertion installation groove 330 may have an inner surface with an inclination that gradually increases from an edge to a central side.

The first gas supply part 410 may have a bottom surface that defines a plane with the bottom surface of the inner lid 310 in a state of being inserted and installed in the insertion installation groove 330.

The inner lid 310 may have a gas introduction groove 340 connected to an end of the gas supply passage 320 on the center side of the bottom surface.

The first gas supply part 410 may further include a diffusion member inserted into the gas introduction groove 340 to diffuse the supplied process gas.

The diffusion member may have an inclined surface on a side surface thereof to gradually increase in height toward the center.

The process chamber 100 may include a gas introduction passage 190 provided to transfer the process gas introduced from the outside to a bottom surface that is in contact with the inner lid part 300, and the inner lid part 300 may descend to be in close contact with the bottom surface 120 so as to connect the gas introduction passage 190 to the gas supply passage 320, thereby supply the process gas to the gas supply passage 320.

The gas supply passage 320 may include a vertical supply passage that is provided at a position corresponding to the gas introduction passage 190 at the edge side of the inner lid 310 and is connected to the gas introduction passage 190, and a horizontal supply passage 322 provided from the vertical supply passage 321 toward the center of the inner lid 310.

The first pressure adjusting part 400 may include a high-pressure adjusting part 430 configured to control the pressure of the processing space S2 to a pressure higher than the normal pressure through the exhaust of the processing space S2 and a pumping controller 440 configured to control the pressure of the processing space S2 to a pressure lower than the normal pressure through pumping of the processing space S2.

The high-pressure controller 430 may include a high-pressure exhaust line 431 installed to allow the processing space S2 and the external exhaust device 1100 to communicate with each other, and a high-pressure control valve 432 installed on the high-pressure exhaust line 431 to control an amount of process gas flowing from the processing space S2 to the external exhaust device 1100 so that the pressure of the processing space S2 is controlled to a pressure higher than the normal pressure, and the pumping controller 440 may include a pumping exhaust line 441 installed to allow the processing space S2 and an external vacuum pump 1200 to communicate with each other, and a pumping control valve 442 installed on the pumping exhaust line 441 to control an amount of process gas flowing from the processing space S2 to the external vacuum pump 1200 so that the pressure of the processing space S2 is controlled to a pressure lower than the normal pressure.

The non-processing space gas exhaust part 520 may include a non-processing space exhaust line 521 installed to allow the gas exhaust hole 180 and the external exhaust device 1100 to communicate with each other, and a non-processing space high-pressure control valve 522 installed on the non-processing space exhaust line 521 to control an amount of filling gas flowing from the non-processing space S1 to the external exhaust device 1100 so that the pressure of the non-processing space S1 is controlled to a pressure higher than the normal pressure.

The non-processing space gas exhaust part 520 may include a non-processing space pumping exhaust line 524 installed to allow the gas exhaust hole 180 and the external vacuum pump 1200 to communicate with each other, and a non-processing space pumping control valve 525 installed on the non-processing space pumping exhaust line 524 to control an amount of filling gas flowing from the non-processing space S1 to the external vacuum pump 1200 so that the pressure of the non-processing space S1 is controlled to a pressure lower than the normal pressure.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a cross-sectional view illustrating a substrate processing apparatus according to the present invention;

FIG. 2 is a graph illustrating a pressure change in each of a processing space and a non-processing space through the substrate processing apparatus of FIG. 1;

FIG. 3 is a cross-sectional view illustrating another example of the substrate processing apparatus according to the present invention;

FIG. 4 is an enlarged cross-sectional view illustrating a gas injection part of the substrate processing apparatus of FIG. 3;

FIG. 5 is a bottom perspective view illustrating a portion of the gas injection part of the substrate processing apparatus of FIG. 3;

FIG. 6 is a view illustrating a state in which a first pressure adjusting part and a second pressure adjusting part are connected to each other in the substrate processing apparatus of FIG. 3 according to a first embodiment;

FIG. 7 is a view illustrating a state in which a first pressure adjusting part and a second pressure adjusting part are connected to each other in the substrate processing apparatus of FIG. 1 according to a second embodiment;

FIG. 8 is a view illustrating a state in which a first pressure adjusting part and a second pressure adjusting part are connected to each other in the substrate processing apparatus of FIG. 1 according to a third embodiment; and

FIG. 9 is a view illustrating a second pressure adjusting part of the substrate processing apparatus of FIG. 1 according to another embodiment.

### DETAILED DESCRIPTION OF THE PREFERRED EMBODIMENTS

Hereinafter, a substrate processing apparatus according to the present invention will be described with reference to the accompanying drawings.

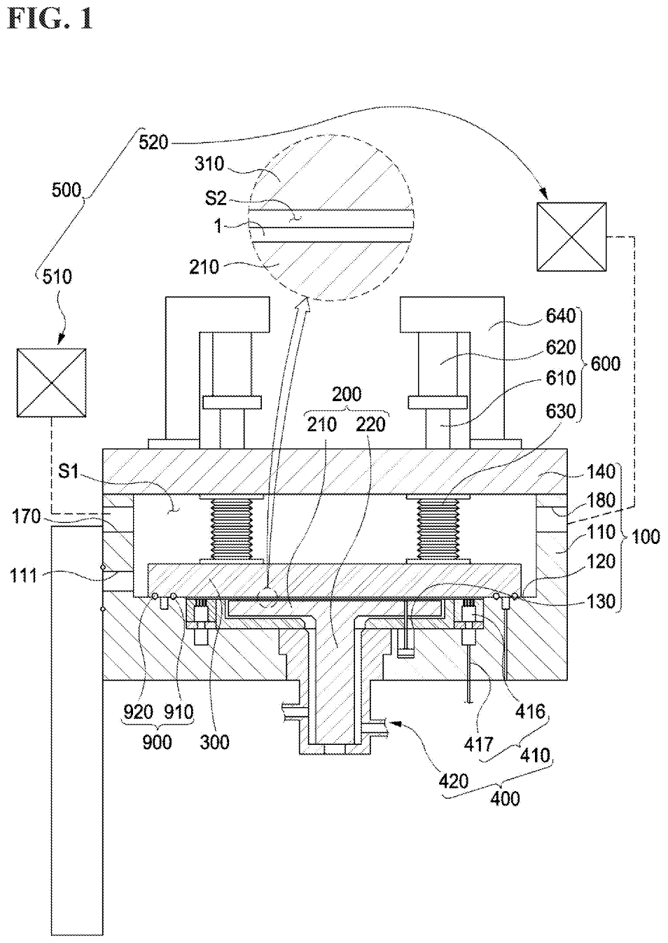

As illustrated in FIG. 1, a substrate processing apparatus according to the present invention includes a process chamber 100 including a chamber body 110 which has an opened upper portion, in which an installation groove 130 is defined at a central side of a bottom surface 120 thereof, and which includes a gate 111 for loading/unloading a substrate 1 is disposed at one side thereof and a top lid 140 coupled to the upper portion of the chamber body 110 to define a non-processing space S1, a substrate support 200 installed to be inserted into the installation groove 130 of the chamber body 110 and having a top surface on which the substrate 1 is seated, an inner lid part 300 which is installed to be vertically movable in the inner space and of which a portion is in close contact with the bottom surface 120 adjacent to the installation groove 130 through descending to define a sealed processing space S2 in which the substrate support 200 is disposed, a first pressure adjusting part 400 communicating with the processing space S2 to adjust a pressure of the processing space S2; and a second pressure adjusting part 500 communicating with the non-processing space S1 to adjust a pressure of the non-processing space S3 independently of the processing space S2.

In addition, the substrate processing apparatus according to the present invention may further include an inner lid driving part 600 installed to pass through a top surface of the process chamber 100 so as to drive the vertical movement of the inner lid part 300.

In addition, the substrate processing apparatus according to the present invention may further include a controller configured to control the pressures of the processing space S2 and the non-processing space S1 through the first pressure adjusting part 400 and the second pressure adjusting part 500.

In addition, the substrate processing apparatus according to the present invention may include a charging member 700 installed between an inner surface of support 200 and installation groove 130 to occupy at least a portion of a space between support 200 and inner surface of the installation groove 130.

In addition, the substrate processing apparatus according to the present invention may further include a substrate support pin part 800 configured to support the substrate 1 loaded into and unloaded from the process chamber 100 and seated on the substrate support 200.

Here, the substrate 1 to be processed may be understood to include all substrates such as substrates used in display devices such as LCD, LED, and OLED, semiconductor substrates, solar cell substrates, glass substrates, and the like.

The process chamber 100 may have a configuration in which the non-processing space S1 is defined therein and thus may have various configurations.

For example, the process chamber 100 may include the chamber body 110 having the opened upper portion and the top lid 140 covering the opened upper portion of the chamber body 110 to define the sealed non-processing space S1 together with the chamber body 110.

In addition, the process chamber 100 may include the bottom surface 120 defining the bottom of the non-processing space S1 and the installation groove 130 defined in the bottom surface 120 to install the substrate support 200.

In addition, the process chamber 100 may further include a gate valve 150 for opening and closing a gate 111 provided at one side of the chamber body 110 to load and unload the substrate 1.

In addition, the process chamber 100 may further include a support pin installation groove 160 defined in a bottom surface of the substrate support 200 to be described later to install a substrate support ring 820.

In addition, the process chamber 100 may include a gas introduction passage 190 provided to transfer the process gas introduced from the outside to a bottom surface that is in contact with the inner lid part 300.

In addition, the process chamber 100 may further include a gas supply hole 170 having one side to which a second gas supply part 510 to be described later is connected to supply a filling gas to the non-processing space S1.

In addition, the process chamber 100 may further include a gas exhaust hole 180 having the other side to which a second gas exhaust part 520 is connected to exhaust the non-processing space S1.

The chamber body 110 may have an opened upper portion to define the sealed non-processing space S1 together with the top lid 140 to be described later.

Here, the chamber body 110 may be made of a metal material including aluminum. As another example, the chamber body 110 may be made of a quartz material and may have a rectangular parallelepiped shape like the chamber that is disclosed in the related art.

The top lid 140 may be coupled to the upper side of the chamber body 110 having the opened upper portion and may be configured to define the sealed non-processing space S1 together with the chamber body 110.

Here, the top lid 140 may be provided in a rectangular shape on a plane to correspond to the shape of the chamber body 110 and may be made of the same material as the chamber body 110.

In addition, the top lid 140 may have a plurality of through-holes so that the inner lid driving part 600 to be described later is installed to pass therethrough, and an end of a bellows 630 to be described later may be coupled to the top lid 140 to prevent various gases and foreign substances from leaking.

The configuration of the top lid 140 may be omitted, and the chamber body 110 may be integrally provided to define the sealed non-processing space S1 therein.

The process chamber 100 may include the bottom surface 120, of which an inner bottom surface defines the bottom of the non-processing space S1, and the installation groove 130 defined to install the substrate support 200.

More specifically, as illustrated in FIG. 1, in the process chamber 100, the installation groove 130 may be defined with a height difference at a central side of the bottom surface to correspond to the substrate support 200 to be described later, and the bottom surface 120 may be defined on an edge of the installation groove 130.

That is, in the process chamber 100, the installation groove 130 for installing the substrate support 200 may be defined with the height difference in the inner bottom surface, and the other portion may be defined as the bottom surface 120 at a height higher than the installation groove 130.

The gate valve 150 may have a configuration for opening and closing the gate 111 disposed at one side of the chamber body 110 to load and unload the substrate 1 and may have various configurations.

Here, the gate valve 150 may be in close contact with or released from the chamber body 110 through vertical driving and forward/backward driving to open or close the gate 111. For another example, the gate valve 150 may open or close the gate 111 through single driving in a diagonal direction. In this process, various types of driving methods disclosed in the related art, such as a cylinder, a can, an electromagnetism, and the like may be applied.

The support pin installation groove 160 may have a configuration for installing the substrate support 200 that supports the substrate 1 and is seated on the substrate support 200 or spaced upward from the substrate support 200 to support the substrate 1 to load or unload the substrate 1 and may have various configurations.

For example, the support pin installation groove 160 may be provided as a planar annular groove corresponding to the substrate support ring 820 so that a substrate support ring 820 to be described later is installed.

Here, the support pin installation groove 160 may be installed to correspond to a position at which the substrate support ring 820 is installed on the bottom surface of the process chamber 100, and more specifically, may be defined in the installation groove 130.

That is, the support pin installation groove 160 may be defined in the installation groove 130 defined with the height difference from the bottom surface 120 and may have a predetermined depth so that the substrate support ring 820 is movable vertically in the installed state.

Thus, in the support pin installation groove 160, the substrate support ring 820 may be installed so that a plurality of substrate support pins 810 are installed to pass through the filling member 700 and the substrate support plate 210 upward.

Since the support pin installation groove 160 is defined in the installation groove 130 to define a predetermined volume, the volume of the processing space S2 defined by the inner lid part 300 to be described later may increase.

To solve this limitation, the filling member 700 to be described laser may be installed in the installation groove 130 to cover the support pin installation groove 160, thereby blocking a space defined by the processing space S2 and the support pin installation groove 160. As a result, the processing space S2 may be defined in minimum volume.

More specifically, if there is no support pin installation groove 160, since a space for the substrate support pin 810 and the substrate support ring 820 to be described later is separately required under the substrate support plate 210, an increase of a dead volume may occur. Thus, to remove the dead volume, the support pin installation groove 160 may be defined so that the substrate support pin 810 and the substrate support ring 820 are inserted therein when descending.

Unlike this, the support pin installation groove 160 may not be installed in the bottom surface 120 of the process chamber 100, but may be defined in the filling member 700 installed in the installation groove 130.

That is, the support pin installation groove 160 may be defined to a predetermined depth in the top surface of the filling member 700, more specifically, to a depth at which the substrate support ring 820 and the substrate support pin 810 are inserted and thus may ascend to support the substrate 1 in a state of being inserted into the filling member 700.

Here, the substrate support pin 810 may be installed to pass through the filling member 700.

The gas supply hole 170 may have a configuration which is provided at one side of the chamber body 110 of the process chamber 100 and to which the second gas supply part 510 is connected.

For example, the gas supply hole 170 may be defined through processing at one side of the chamber body 110 or may be provided by being installed in a through-hole defined in one side of the chamber body 110.

Thus, in the gas supply hole 170, the second gas supply part 510 is installed to connect the non-processing space S1 to the second gas supply part 510, and thus, the filling gas may be supplied to the non-processing space S1.

The gas exhaust hole 180 may have a configuration which is provided at the other side of the chamber body 110 of the process chamber 100 and to which the second gas exhaust part 520 is connected.

For example, the gas exhaust hole 180 may be defined through processing at the other side of the chamber body 110 or may be provided by being installed in a through-hole defined in the other side of the chamber body 110.

Thus, in the gas exhaust hole 180, the second gas exhaust part 520 may be installed to exhaust the non-processing space S1.

The gas introduction passage 190 may have a configuration that is provided to transfer the process gas introduced from the outside to the bottom surface of the process chamber 100, i.e., a position that is in contact with the inner lid part 300, and may have various configurations.

For example, the gas introduction passage 190 may be connected to an external process gas storage part through the bottom surface or the side surface of the chamber body 110 and may be disposed on an end at a position of the bottom surface, which corresponds to the inner lid part 300, in particular, a gas supply passage 320 to be described later.

Thus, the gas introduction passage 190 may be connected to the gas supply passage 320 when the inner lid part 300 descends to be in close contact with the bottom surface 120 to transfer the process gas to the supply passage 320.

In this case, the gas introduction passage 190 may be provided through a pipe installed in the bottom surface of the process chamber 100, and for another example, the gas introduction passage 190 may be provided through processing inside the chamber body 110.

In addition, the gas introduction passage 190 may be provided at at least one position of the positions adjacent to the edge of the substrate 1 corresponding to the gas supply passage 320 to be described later on the bottom surface of the process chamber 100.

The substrate support 200 may have a configuration that is installed in the processing space S2 so that the substrate 1 is seated on a top surface thereof and may have various configurations.

That is, the substrate support 200 may support the substrate 1 to be processed by seating the substrate 1 on the top surface thereof and may be fixed during the substrate processing process.

In addition, the substrate support 200 may include a heater therein to provide a temperature atmosphere in the processing space S2 for the substrate processing.

For example, the substrate support 200 may include a substrate support plate 210 having a planar circular shape on which the substrate 1 is seated on a top surface thereof, and a substrate support shaft 220 passing through the bottom surface of the process chamber 100 so as to be connected to the substrate support plate 210.

In addition, the substrate support 200 may include a heater installed in the substrate support plate 210 to heat the substrate 1 seated on the substrate support plate 210.

The substrate support plate 210 may have a configuration in which the substrate 1 is seated on the top surface thereof and may be provided as a plate having a planar circular shape corresponding to the shape of the substrate 1.

Here, the substrate support plate 210 may be provided with a heater therein to create a process temperature for the substrate processing in the processing space S2. Here, the process temperature may be about 400° C. to 700° C.

The substrate support shaft 220 may have a configuration that passes through the bottom surface of the process chamber 100 so as to be connected to the substrate support plate 210 and may have various configurations.

The substrate support shaft 220 may pass through the bottom surface of the process chamber 100 so as to be coupled to the substrate support plate 210, and various conductors for supplying power to the heater may be installed in the substrate support shaft 220.

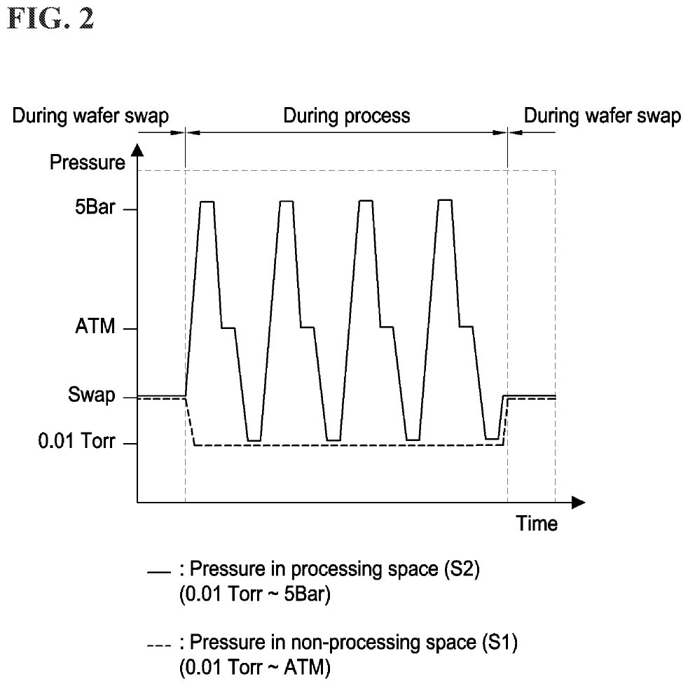

As illustrated in FIG. 2, the substrate processing apparatus according to the present invention may be an apparatus for performing the substrate processing in which a high-pressure and low-pressure atmosphere is repeatedly changed and created within a short time, and more particularly, it is necessary to repeatedly change a pressure range of about 0.01 Torrs at a pressure change rate of about 1 Bar/s.

However, when considering a vast space volume of the inner space of the chamber body 110, the above-described pressure change rate may not be achieved, and thus, there is a need to minimize the volume of the processing space S2 for the substrate processing.

For this, the substrate processing apparatus according to the present invention includes an inner lid part 300 which is installed to be vertically movable in the inner space and of which a portion is in close contact with the process chamber 100 through descending to define the sealed processing space S2, in which the substrate support 200 is disposed.

The inner lid part 300 may have a configuration which is installed to be vertically movable in the inner space and of which a portion is in close contact with the process chamber 100 through the descending to define the sealed processing space S2, in which the substrate support 200 is disposed.

That is, the inner lid part 300 may be installed to be movable vertically in the inner space, and a portion of the inner lid part 300 may be in close contact with the bottom surface 120 adjacent to the installation groove 130 through the descending to divide the inner space into the processing space S2, in which the substrate support 200 is, and other non-processing space S3.

Thus, the inner lid part 300 may be installed to be vertically movable at an upper side of the substrate support 200 in the inner space so as to be in close contact with at least a portion of the inner surface of the process chamber 110 through the descending, and thus, the sealed processing space S2 may be defined between the inner lid part 300 and the inner bottom surface of the process chamber 100 as necessary.

Thus, the substrate support 200 may be disposed in the processing space S2 to perform the substrate processing on the substrate 1 seated on the substrate support 200 in the processing space S2 having the minimized volume.

For example, an edge of the inner lid part 300 may be in close contact with the bottom surface 120 through the descending to define the sealed processing space S2 between the bottom surface and the inner bottom surface of the process chamber 100.

For another example, the edge of the inner lid part 300 may be in close contact with the inner surface of the process chamber 100 through the descending to define the sealed processing space S2.

The edge of the inner lid part 300 may be in close contact with the bottom surface 120 through the descending to define the sealed processing space S2, and the substrate support 200 installed in the installation groove 130 may be disposed within the processing space S2.

That is, as illustrated in FIG. 1, the edge of the inner lid part 300 may be in close contact with the bottom surface 120 disposed at a high position with a height difference with respect to the installation groove through the descending to define the sealed processing space S2 between the bottom surface and the installation groove 130.

Here, the substrate support 200, more specifically, the substrate support plate 210 may be installed in the installation groove 130 to minimize the volume of the processing space S2 and dispose the substrate 1 to be processed on the top surface thereof.

In this process, to minimize the volume of the processing space S2, the installation groove 130 may have a shape corresponding to the substrate support 200 installed in the processing space S2, more particularly, may be provided as a groove having a cylindrical shape corresponding to the circular substrate support plate 210.

That is, the installation groove 130 may have a shape corresponding to that of the substrate support plate 210 so that a remaining space except for the space, in which the substrate support plate 210 and an insulator part are installed, in the installation space, in which the installation groove 130 is defined, is minimized.

In this process, to prevent an interference between the substrate 1 seated on the top surface of the substrate support plate 210 and the inner lid part 300 from occurring, the bottom surface 120 may be disposed at a height higher than that of the top surface of the substrate 1 seated on the substrate support 200.

It means that, as a distance between the substrate 1 seated on the substrate support 200 and the bottom surface of the inner lid part 300 increases, the processing space

S2 increases also in volume. Thus, the height of the bottom surface 120 may be set at a position at which the distance is minimized while preventing the interference between the substrate 1 and the inner lid part 300 from occurring.

The inner lid part 300 may have a configuration that moves vertically through the inner lid driving part 600 and may have various configurations.

The inner lid part 300 may have a configuration that is vertically movable in the inner space through the inner lid driving part 600.

Here, the inner lid part 300 may cover the installation groove 130 on a plane, and the edge of the inner lid part 300 may have a size corresponding to a portion of the bottom surface 120. In addition, the edge may be in close contact with the bottom surface 120 to define the sealed processing space S2 between the installation groove 130 and the inner lid part 300.

For another example, the edge of the inner lid part 300 may be in close contact with the inner surface of the process chamber 100 to define the processing space S2.

In addition, to effectively achieve and maintain the process temperature in the sealed processing space S2 defined according to the vertical movement, the inner lid part 300 may be made of a material having an excellent thermal insulation effect that is capable of preventing the temperature of the processing space S2 from being lost to the inner space.

In addition, the inner lid part 300 may be provided with a gas supply passage 320 therein to transfer the process gas received from the above-described gas introduction passage 190 to a first gas supply part 410 to be described later.

For example, the inner lid part 300 may include an inner lid 310 that moves vertically in the inner space, and a gas supply passage 320 provided to communicate with the processing space S2 inside the inner lid 310.

In addition, the inner lid 310 may have an insertion groove 330 in which the first gas supply part 410 to be described later is inserted and installed in the bottom surface.

In addition, the inner lid 310 may have a gas introduction groove 340 connected to an end of the gas supply passage 320 on the center side of the bottom surface.

The inner lid 310 may have a configuration that moves vertically in the inner space and may be provided in a size and shape to cover the installation groove 130 of the process chamber 100.

For example, the inner lid 310 may have a circular plate shape and may be provided in a planar shape corresponding to the substrate 1.

The gas supply passage 320 may have a configuration that is provided to communicate with the processing space S2 inside the inner lid 310, and may have various configurations.

Here, the gas supply passage 320 may be provided through a pipe installed inside the inner lid 310, like the gas introduction passage 190 described above, and for another example, the gas supply passage 320 may be provided by processing the inside of the inner lid 310.

The gas supply passage 320 may be in close contact with the bottom surface 120 through descending of the inner lid 310 so as to be connected to the gas introduction passage 190 and may receive the process gas through the gas introduction passage 190 to supply the process gas to the first gas supply part 410 through the gas introduction groove 340 to be described later.

For this, the gas supply passage 320 may include a vertical supply passage that is provided at a position corresponding to the gas introduction passage 190 at the edge side of the inner lid 310 and is connected to the gas introduction passage 190, and a horizontal supply passage 322 provided from the vertical supply passage 321 toward the center of the inner lid 310.

That is, the vertical supply passage 321 may be provided in the vertical direction at a position corresponding to the gas introduction passage 190 on a plane at a side of the edge of the inner lid 310 to receive the process gas from the gas introduction passage 190, thereby transferring the process gas to the gas introduction groove 340 through the horizontal supply passage 322 that extends from the vertical supply passage 321 and is provided toward a center of the inner lid 310.

In this case, since the process gas is received from the gas introduction passage 190 through the vertical supply passage 321, to minimize the leakage of the process gas through the contact surface between the inner lid part 300 and the process chamber 100, the vertical supply passage 321 may have an inner diameter greater than or equal to that of the gas introduction passage 190.

The insertion installation groove 330 may have a configuration in which at least a portion of the first gas supply part 410 to be described later is inserted and installed into the bottom surface of the inner lid 310.

For this, the insertion installation groove 330 may be provided in a shape corresponding to the first gas supply part 410 on the bottom surface of the inner lid 310, and a gas introduction groove 340 may be additionally defined at the central side.

Here, in the insertion installation groove 330, a diffusion space S3 may be defined between the insertion installation groove 330 and the first gas supply part 410 to be described later to increase in volume of the diffusion space S3, and also, the inner surface may have an inclination that gradually increases from the edge toward the central side may be defined.

That is, the insertion installation groove 330 may have an inclination that increases in radius toward the edge toward the lower side so that the inner surface has a triangular pyramid shape.

The gas introduction groove 340 may have a configuration that is connected to an end of the gas supply passage 320 at the central side of the bottom surface to inject the process gas toward the diffusion space S3.

Here, the gas introduction groove 340 may have an inner surface defined in the vertical direction to supply the process gas, and for another example, the inclination may be defined so that a diameter increases downward, and thus, the supplied process gas may be induced to be diffused and supplied in the horizontal direction, i.e., toward the edge.

The first pressure adjusting part 400 may have a configuration that communicates with the processing space S2 to adjust the pressure in the processing space S2 and may have various configurations.

For example, the first pressure adjusting part 400 may include a first gas supply part 410 configured to supply the process gas to the processing space S2 and a first gas exhaust part 420 configured to exhaust the processing space S2.

In addition, the first pressure adjusting part 400 may include, as one embodiment of the first gas exhaust part 420, a high-pressure controller 430 configured to control the pressure of the processing space S2 to a pressure higher than the normal pressure through the exhaust of the processing space S2 and a pumping controller 440 configured to control the pressure of the processing space S2 to a pressure lower than the normal pressure through pumping of the processing space S2.

That is, the first pressure adjusting part 400 may supply the process gas to the processing space S2 and adequately exhaust the processing space S2 to adjust the pressure of the processing space S2. Thus, as illustrated in FIG. 2, high-pressure and low-pressure pressure atmospheres may be repeatedly changed and created within a short time in the processing space S2.

Here, more specifically, the pressure of the processing space S2 may be repeatedly changed at a pressure change rate of about 1 Bar/s in a pressure range of about 5 Bars to about 0.01 Torrs.

Particularly, in this case, the first pressure adjusting part 400 may fall the pressure of the processing space S2 from a first pressure to a normal pressure, and thus, the pressure of the processing space S2 may decrease step by step from the normal pressure to a second pressure.

In addition, the first pressure adjusting part 400 may sequentially and repeatedly change the pressure of the processing space S2 from the first pressure to the second pressure and then to the first pressure several times to perform the substrate processing.

The first gas supply part 410 may have a configuration that communicates with the processing space S2 to supply the process gas, and may have various configurations.

For example, as illustrated in FIG. 1, the first gas supply part 410 may include a gas supply nozzle 416 exposed to the processing space S2 to supply the process gas into the processing space S2 and a gas supply passage 417 passing through the process chamber 100 so as to be connected to the gas supply nozzle 416 and transfer the process gas supplied through the gas supply nozzle 416.

Here, as illustrated in FIG. 1, the first gas supply part 410 may be installed to be adjacent to the substrate support 200 on the edge of the installation groove 130 to supply the process gas to the processing space S2.

The gas supply nozzle 416 may have a configuration that is exposed to the processing space S2 to supply the process gas into the processing space S2 and may have various configurations.

For example, the gas supply nozzle 416 may be installed to be adjacent to a side surface of the substrate support plate 210 on the edge of the installation groove 130 and may inject the process gas upward or toward the substrate support plate 210 to supply the process gas into the processing space S2.

Here, the gas supply nozzle 416 may be provided to surround the substrate support plate 210 on the edge of the installation groove 130 and may inject the process gas from at least a portion of the side surface of the substrate support plate 210 on the plane.

For example, the gas supply nozzle 416 may inject the process gas from the edge of the installation groove 130 toward the bottom surface of the inner lid part 300 and may supply the process gas to generate a desired pressure within a short time in the processing space S2 according to the minimized volume of the processing space S2.

The gas supply passage 417 may pass through the bottom surface of the process chamber 100 so as to be connected to an external process gas storage part and may receive the process gas to supply the process gas to the process gas supply nozzle 416.

Here, the gas supply passage 417 may be a pipe installed to pass through the bottom surface of the process chamber 100. For another example, the gas supply passage 420 may be provided by processing the bottom surface of the process chamber 100.

The gas supply passage 417 may have a configuration corresponding to the gas introduction passage 190 described above and may be replaced with or connected to the gas introduction passage 190.

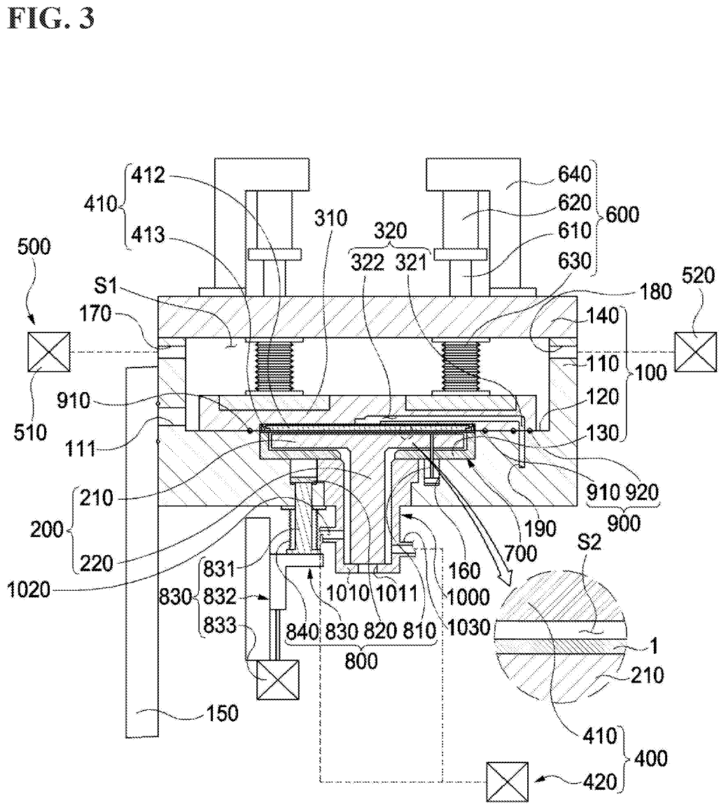

In addition, for another example, as illustrated in FIG. 3, the first gas supply part 410 may include an injection plate 412 disposed under the inner lid part 300 and provided with a plurality of injection holes 411 and an injection plate support 413 supporting an edge of the injection plate 412 and coupled to the bottom surface of the inner lid part 300.

The first gas supply part 410 may further include a plurality of coupling members 414 passing through the injection plate support 413 so as to be coupled to the inner lid part 300.

The injection plate 412 may be disposed below the inner lid part 300 and may have a configuration in which the process gas is injected into the processing space S2 through the plurality of injection holes 411.

Here, the injection plate 412 may be disposed to be spaced downward from the inner lid part 300 by a preset distance to define a diffusion space S3 in which the process gas is diffused between the injection plate 412 and the inner lid part 300.

The injection plate 412 may be made of a metal or quartz material. Particularly, the injection plate 412 may prevent heat generated from the substrate support 200 from being directly transfer to the inner lid part 300, thereby preventing the inner lid part 300 from being bent or damaged.

For this, the injection plate 412 may be made of SUS or quartz material having excellent thermal insulation performance, and a surface treatment capable of enhancing the thermal insulation performance or reflecting heat may be performed on the bottom surface.

The injection holes 411 may pass through the injection plate 412 in the vertical direction and may be provided in a plurality over the entire area to enable uniform process gas injection.

The injection plate support 413 may have a configuration that supports and installs the injection plate 412 described above, and may have various configurations.

For example, the injection plate support 413 may be provided in an annular shape to surround an edge of the circular injection plate 412 and may support the edge of the injection plate 412 to induce the installation of the injection plate 412.

For this, the injection plate support 413 may protrude toward the center on the inner surface to provide a support stepped part 415, on which the edge of the bottom surface of the injection plate 412 is seated, thereby preventing the injection plate 412 and the inner lid part 300 from being in direct contact with each other, serving as a buffer due to thermal deformation of the injection plate 412, and preventing the inner lid part 300 from being directly heated.

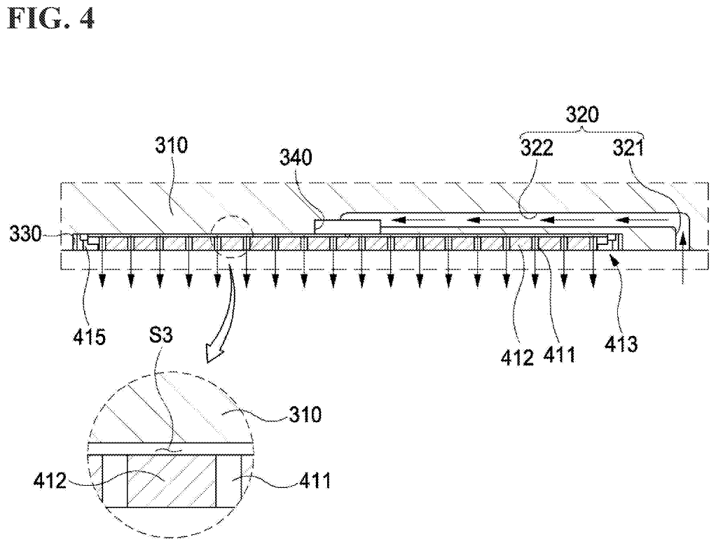

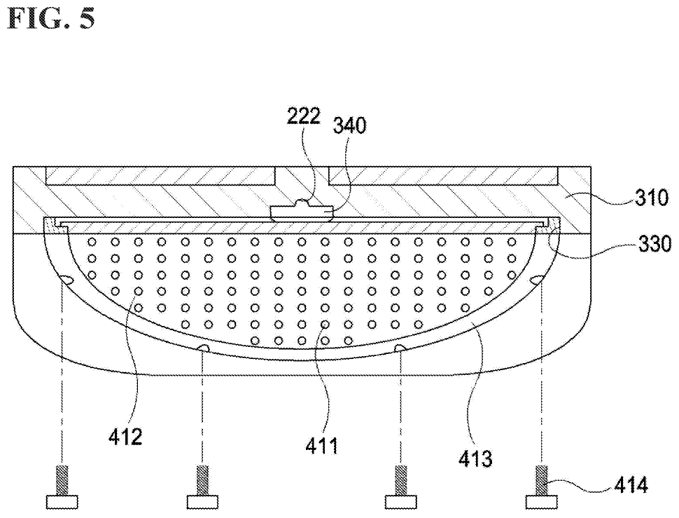

As illustrated in FIGS. 4 and 5, the injection plate support 413 may be penetrated through a plurality of coupling members 414, and the coupling member 414 may be coupled to the bottom surface of the inner lid part 310 so as to be fixed and installed, and thus, the injection plate 412 may be supported.

In this case, the first gas supply part 410 may be installed to be inserted into the insertion installation groove 330, and the bottom surface, i.e., bottom surfaces of the injection plate 412 and the injection plate support 413 may provide a plane with the bottom surface of the inner lid 310.

The first gas supply part 410 may further include a diffusion member (not shown) that is inserted into the gas introduction groove 340 to diffuse the supplied process gas in the horizontal direction.

Here, the diffusion member has a cone or truncated cone shape in a forward direction in which an inclined surface is provided on a side surface so that a height increases toward the center, and the process gas supplied through the gas introduction groove 340 may be induced to be diffused toward the edge in the horizontal direction.

For this, the diffusion member may be installed while being supported on the bottom surface of the inner lid 310, and for another example, the diffusion member may be installed by being seated on the top surface of the injection plate 412.

The first gas exhaust part 420 may have a configuration that exhausts the processing space S2, and may have various configurations.

For example, the first gas exhaust part 420 may include an external exhaust device communicating with the processing space S2 and installed outside, and thus, an exhaust amount to processing space S2 may be controlled to adjust the pressure of the processing space S2.

In more detail, the first gas exhaust part 420 may include a high-pressure controller 430 configured to control the pressure of the processing space S2 to a pressure higher than the normal pressure through the exhaust of the processing space S2 and a pumping controller 440 to control the pressure of the processing space S2 to a pressure lower than the normal pressure through pumping of the processing space S2.

The high-pressure adjusting part 430 may have a configuration that controls the pressure in the processing space S2 to a pressure higher than the normal pressure through the exhaust to the processing space S2, and may have various configurations.

That is, the high-pressure adjusting part 430 may have a configuration that exhausts the processing space S2 to adjust the pressure of the processing space S2 when the pressure in the processing space S2 is higher than the normal pressure.

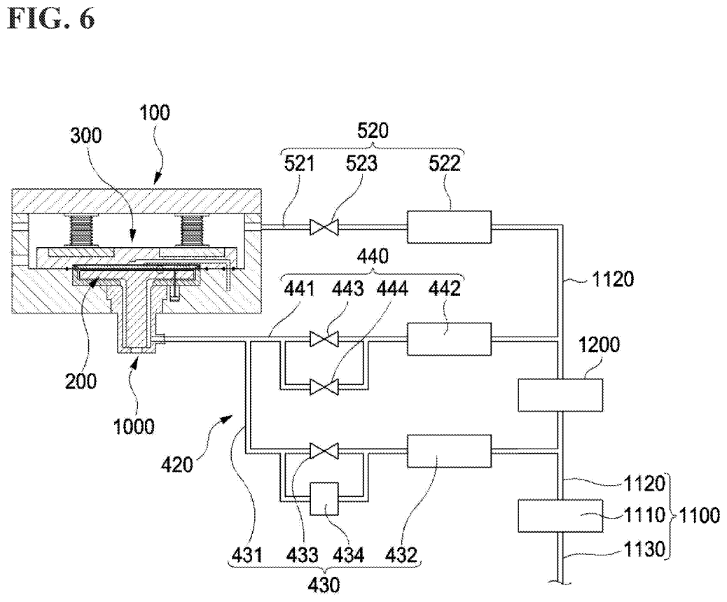

For example, as illustrated in FIG. 6, the high-pressure adjusting part 430 may include a high-pressure exhaust line 431 installed so that a processing space exhaust port provided in a manifold part 1000 to be described later and an external exhaust device 1100 communicate with each other, and a high-pressure control valve 432 installed on the high-pressure exhaust line 431 to control the pressure of the process gas introduced into the processing space S2.

In addition, the high-pressure adjusting part 430 may further include a high-pressure opening/closing valve 433 installed on a front end of the high-pressure control valve 432 in the high-pressure exhaust line 431 to determine an opening or closing of the high-pressure exhaust line 431.

In addition, the high-pressure adjusting part 430 may further include a relief valve 434 installed in parallel with the high-pressure opening/closing valve 433 in the high-pressure exhaust line 431.

The high-pressure exhaust line 431 may be installed so that the processing space exhaust port provided in the manifold part 1000 and the external exhaust device 1100 communicate with each other to provide a passage through which the process gas in the processing space S2 is transferred.

The high-pressure control valve 432 may have a configuration that is installed on the high-pressure exhaust line 431 to control the pressure of the process gas introduced into the processing space S2 and also may control an amount of exhaust through the high-pressure exhaust line 431.

In this case, the high-pressure control valve 432 may be controlled through a controller (not shown) that checks the pressure through a pressure gauge (not shown) installed on the high-pressure exhaust line 431 and transmits a control signal.

The high-pressure opening/closing valve 433 may have a configuration that is installed on the front end of the high-pressure control valve 432 in the high-pressure exhaust line 431 to determine the opening or closing of the high-pressure exhaust line 431.

That is, the high-pressure opening/closing valve 433 may open the high-pressure exhaust line 431 when the processing space S2 is in a high-pressure state through the opening and closing of the high-pressure exhaust line 431 and may close the high-pressure exhaust line 431 when the processing space S2 is in a low pressure state.

The relief valve 434 may have a configuration that is installed in parallel with the high-pressure opening/closing valve 433 on the high-pressure exhaust line 431 and may be mechanically opened for the exhaust when a preset high pressure is detected.

That is, the relief valve 434 may be mechanically opened when the high pressure, for example, a pressure of about 5 Bars or more is detected to improve the safety, thereby preventing the device from being damaged due to the high pressure.

The pumping controller 440 may include a pumping exhaust line 441 installed so that a processing space exhaust port and an external vacuum pump 1200 communicate with each other and a pumping control valve 442 installed on the pumping exhaust line 441 to control the pressure of the processing space to a pressure less than the normal pressure by pumping the processing space S2.

In addition, the pumping controller 440 may further include a pumping opening/closing valve installed on a front end of the pumping control valve 442 in the pumping exhaust line 441 to determine an opening or closing of the pumping exhaust line 441.

In addition, the pumping controller 440 may further include a slow pumping valve 444 installed in parallel with the pumping opening/closing valve 443 in the pumping exhaust line 441 to control an amount of pumping.

The pumping exhaust line 441 may be installed so that the processing space exhaust port provided in the manifold part 1000 and the external vacuum pump 1200 communicate with each other to provide a passage through which the process gas in the processing space S2 is transferred.

The pumping control valve 442 may have a configuration that is installed on the pumping exhaust line 441 to control the pressure of the process gas, which is in a state of a low-pressure less than the normal pressure, introduced into the processing space S2 and also may control an amount of exhaust through the pumping exhaust line 441.

In this case, the pumping control valve 442 may be controlled through a controller (not shown) that checks the pressure through a pressure gauge (not shown) installed on the pumping exhaust line 441 and transmits a control signal.

The pumping opening/closing valve 443 may have a configuration that is installed on the front end of the pumping control valve 442 in the pumping exhaust line 441 to determine the opening or closing of the pumping exhaust line 441.

That is, the pumping opening/closing valve 443 may close the pumping exhaust line 441 when the processing space S2 is in a high-pressure state through the opening and closing of the pumping exhaust line 441 and may open the pumping exhaust line 441 when the processing space S2 is in a low pressure state.

The slow pumping valve 444 may have a configuration that is installed in parallel with the pumping opening/closing valve 443 on the pumping exhaust line 441, i.e., may have a configuration that is opened when it is necessary to control the pumping amount during an initial pumping process or pumping to adjust the pumping amount.

Various embodiments for installation with the high-pressure controller 430 and the manifold part 1000 of the pumping controller 440 according to the present invention will be described below with reference to the accompanying drawings.

As illustrated in FIG. 6, in the high-pressure adjusting part 430 according to the present invention, as a first embodiment, the high-pressure exhaust line 431 may be installed so that the processing space exhaust port provided in the manifold part 1000 and the external exhaust device 1100 communicate with each other, and more specifically, one end may be branched from the front end of the pumping control valve 442 in the pumping exhaust line 441 and then be connected, and the other end may be connected to the external exhaust device 1100.

That is, in the high-pressure adjusting part 430, in a state in which the pumping exhaust line 441 is installed so that the processing space exhaust port and the external vacuum pump 1200 communicate with each other, the high-pressure exhaust line 431 may be installed so that the front end of the pumping control valve 442 and the external exhaust device 1100 communicate with each other in the pumping exhaust line 441.

As a result, the high-pressure adjusting part 430 may be provided to be branched from the pumping exhaust line 441 connected to the processing space exhaust port when a single processing space exhaust port is provided in the manifold part 1000. For this, the high-pressure exhaust line 431 may be installed to be branched and connected to the pumping exhaust line 441 at the front end of the pumping control valve 442.

In this case, the pumping exhaust line 441 of the pumping controller 440 may be coupled to the single processing space exhaust port provided in the manifold part 1000, and the high-pressure exhaust line 431 may be branched and installed at the front end of the pumping opening/closing valve 443 in the pumping exhaust line 441.

In this case, the process gas exhausted through the single processing space exhaust port may be exhausted by properly opening and closing the above-described pumping opening/closing valve 443 and the high-pressure opening/closing valve 433 according to the pressure, i.e., the high pressure and low pressure with respect to the normal pressure.

The external exhaust device 1100 may include a harmful material removing part 1110 that removes a harmful material from the discharged exhaust gas and an external exhaust line 1120 installed so that the harmful material removing part 1110 and the external vacuum pump 1200 communicate with each other.

Here, the high-pressure exhaust line 431 may have one end connected to the front end of the processing space pumping control valve 442 in the pumping exhaust line 441 and the other end connected to the external exhaust line 1120, and thus, the high-pressure controller 430 may communicate with the external exhaust device 1100.

In addition, for another example, the high-pressure exhaust line 431 may have one end connected to the front end of the processing space pumping control valve 442 in the pumping exhaust line 441 and the other end directly connected to the harmful material removing part 1110, and thus, the high-pressure controller 430 may communicate with the external exhaust device 1100.

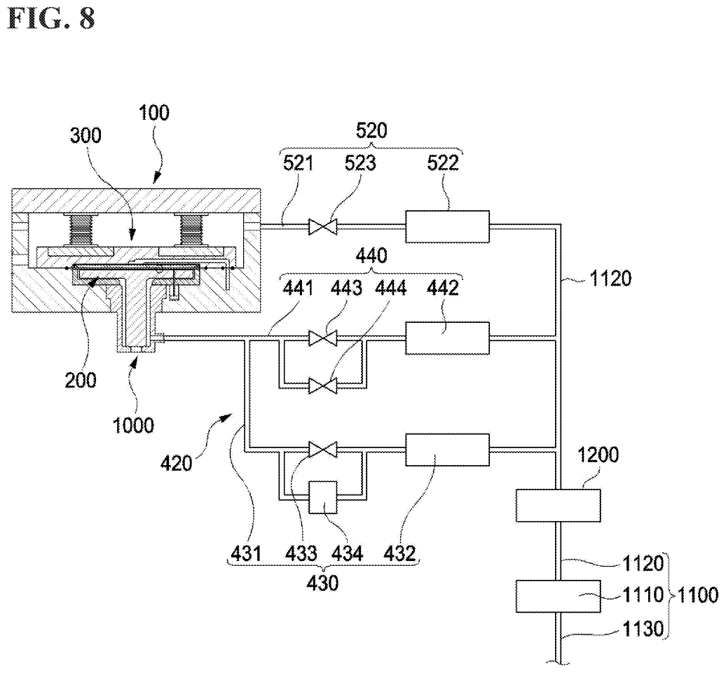

As a third embodiment, as illustrated in FIG. 8, in a state in which the pumping controller 440 is installed so that the processing space exhaust port and the external vacuum pump 1200 communicate with each other through the pumping exhaust line 441, since the high-pressure exhaust line 431 is installed so that the front end and the rear end of the pumping control valve 442 in the pumping exhaust line 441 communicate with each other, the high-pressure controller 430 may control an amount of process gas flowing from the processing space S2 to the external vacuum pump 1200 through the high-pressure control valve 432.

Here, the pumping controller 440 and the high pressure adjusting part 430 may have configurations that communicate with the same external vacuum pump 1200, respectively, and for another example, an independent separate external vacuum pump 1200 may communicate with the pumping controller 440 and the high-pressure adjusting part 430.

For another example of the third embodiment, in a state in which the pumping controller 440 is installed so that the processing space exhaust port and the external vacuum pump 1200 communicate with each other through the pumping exhaust line 441, since the high-pressure exhaust line 431 is directly connected to the front end of the pumping control valve 442 and the external vacuum pump 1200 in the pumping exhaust line 441, the high-pressure controller 430 may adjust an amount of process gas flowing from the processing space S2 to the external vacuum pump 1200 through the high-pressure control valve 432.

In this case, the pumping controller 440 and the high pressure adjusting part 430 may also have configurations that communicate with the same external vacuum pump 1200, respectively, and for another example, an independent separate external vacuum pump 1200 may communicate with the pumping controller 440 and the high-pressure adjusting part 430.

For another example, in a state in which the high-pressure controller 430 is installed so that the processing space exhaust port and the external vacuum pump 1200 communicate with each other through the pumping exhaust line 431, since the pumping controller 440 is installed so that the front end of the high-pressure control valve 432 and the external vacuum pump 1200 in the high-pressure exhaust line 431 communicate with each other through the pumping exhaust line 441, an amount of process gas flowing from the processing space S2 to the external vacuum pump 1200 may be controlled through the pumping control valve 442.

In this case, the pumping controller 440 and the high pressure adjusting part 430 may also have configurations that communicate with the same external vacuum pump 1200, respectively, and for another example, an independent separate external vacuum pump 1200 may communicate with the pumping controller 440 and the high-pressure adjusting part 430.

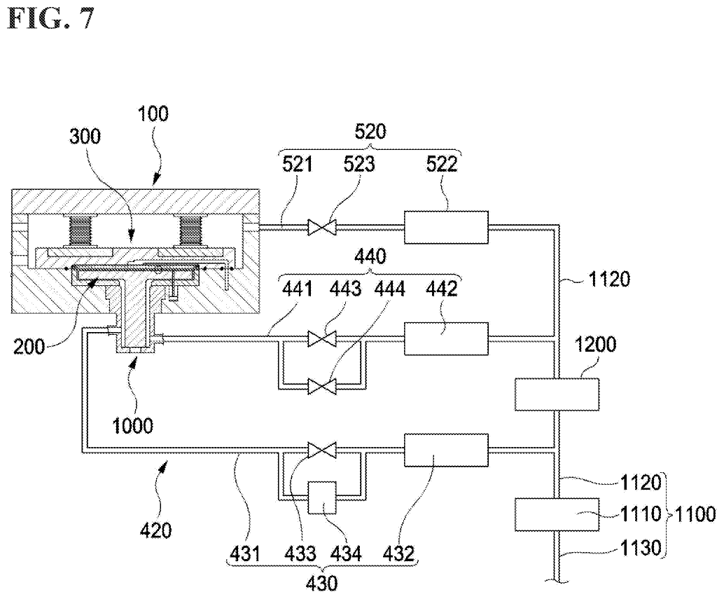

As a second embodiment, as illustrated in FIG. 7, the manifold part 1000 may be provided with a high-pressure exhaust port 1020 connected to the high-pressure controller 430 and a pumping exhaust port 1030 connected to the pumping controller 440.

In this case, one end of the above-described high-pressure exhaust line 431 may be coupled to the high-pressure exhaust port 1020, and the other end may be coupled to the external exhaust device 1100 to exhaust the high-pressure process gas through the high-pressure exhaust line 431.

In addition, in independent of the high pressure adjusting part 430, one end of the pumping exhaust line 441 in the pumping controller 440 may be connected to the pumping exhaust port 1030, and the other end may be connected to the external vacuum pump 1200 to exhaust the low-pressure process gas through the low-pressure exhaust line 421.

More specifically, in the high-pressure adjusting part 430, in a state in which the pumping exhaust line 441 is installed so that the pumping exhaust port 1030 and the external vacuum pump 1200 communicate with each other, since the high-pressure exhaust line 431 is installed so that the high-pressure exhaust port 1020 and the external exhaust device 1100 communicate with each other, the amount of process gas flowing from the processing space S2 to the external exhaust device 1100 in the processing space S2 may be controlled to control the pressure of the processing space S2 to a pressure higher than the normal pressure.

Here, the high-pressure exhaust line 431 may have one end connected to the high-pressure exhaust port 1020 in the pumping exhaust line 441 and the other end connected to the external exhaust line 1120, and thus, the high-pressure controller 430 may communicate with the external exhaust device 1100.

In addition, for another example, the high-pressure exhaust line 431 may have one end connected to the high-pressure exhaust port 1020 in the pumping exhaust line 441 and the other end connected to the harmful material removing part 1110, and thus, the high-pressure controller 430 may communicate with the external exhaust device 1100.

For another example, in a state in which the pumping controller 440 is installed so that pumping exhaust port 1030 and the external vacuum pump 1200 communicate with each other through the pumping exhaust line 441, since the high-pressure exhaust line 431 is installed so that the high-pressure exhaust line 431 and the rear end of the pumping control valve 442 in the high-exhaust port 1020 and the pumping exhaust line 441 communicate with each other, the high-pressure controller 430 may control the amount of process gas flowing from the processing space S2 to the external vacuum pump 1200 through the high-pressure control valve 432.

Here, the pumping controller 440 and the high pressure adjusting part 430 may have configurations that communicate with the same external vacuum pump 1200, respectively, and for another example, an independent separate external vacuum pump 1200 may communicate with the pumping controller 440 and the high-pressure adjusting part 430.

For another example, in a state in which the pumping controller 440 is installed so that the processing space exhaust port and the external vacuum pump 1200 communicate with each other through the pumping exhaust line 441, since the high-pressure exhaust line 431 is directly connected to the high-pressure exhaust port 1020 and the external vacuum pump 1200, the high-pressure controller 430 may adjust an amount of process gas flowing from the processing space S2 to the external vacuum pump 1200 through the high-pressure control valve 432.

In this case, the pumping controller 440 and the high pressure adjusting part 430 may also have configurations that communicate with the same external vacuum pump 1200, respectively, and for another example, an independent separate external vacuum pump 1200 may communicate with the pumping controller 440 and the high-pressure adjusting part 430.

The first pressure adjusting part 500 may have a configuration that communicates with the non-processing space S1 to adjust the pressure in the non-processing space S1 and may have various configurations.

Particularly, the second pressure adjusting part 500 may adjust the pressure in the non-processing space S1 defined separately from the processing space S2 independently of the processing space S2.

For example, the second pressure adjusting part 500 may include a second gas supply part 510 communicating with the non-processing space S1 to supply a filling gas to the non-processing space S3 and a second gas exhaust part 520 performing exhaust for the non-processing space S1.

The second gas supply part 510 may be connected to the above-described gas supply hole 170 to supply the filling gas to the non-processing space S1, and thus, the pressure to the non-processing space S1 may be adjusted.

The second gas exhaust part 520 may be connected to the above-described gas exhaust hole 180 to exhaust the non-processing space S1, and thus, the pressure of the non-processing space S1 may be adjusted.

Any configuration may be applied to the second gas supply part 510 and the second gas exhaust part 520 as long as the second gas supply part 1310 and the second gas exhaust part 1320 are configured to supply and exhaust the filling gas that is disclosed in the related art.

For example, the second gas exhaust part 520 may include a non-processing space exhaust line 521 having one end connected to the gas exhaust hole 180 and the other end connected to the external vacuum pump 1200 and a non-processing space high-pressure control valve 522 installed on the non-processing space exhaust line 521 to control a pressure of the non-processing space S1.

In addition, the second gas exhaust part 520 may further include a pressure opening/closing valve 523 installed at the front end of the non-process space high-pressure control valve 522 in the non-process space exhaust line 521 to determine an opening or closing of the non-process space exhaust line 521.

The non-processing space exhaust line 521 may be installed so that the gas exhaust hole 180 provided in the process chamber 100 and the external vacuum pump 1200 communicate with each other to provide a passage through which the process gas in the processing space S2 is transferred.

The non-processing space high-pressure control valve 522 may have a configuration that is installed on the non-processing space exhaust line 521 to control a pressure of the filling gas, which is in a state of a high pressure higher than the normal pressure, introduced into the non-processing space Si and also may control an amount of exhaust through the non-processing space exhaust line 521.

Here, the non-processing space high-pressure control valve 522 may be controlled through a controller (not shown) that checks the pressure through a pressure gauge (not shown) installed on the non-processing space exhaust line 521 and transmits a control signal.

The pressure opening/closing valve 523 may have a configuration that is installed on the front end of the non-processing space high-pressure control valve 522 in the non-processing space exhaust line 521 to determine the opening or closing of the non-processing space exhaust line 521.

That is, the pressure opening/closing valve 523 may determine whether to exhaust the non-processing space S1 through the opening/closing of the non-processing space exhaust line 521.

As a result, the second gas exhaust part 520 may control the pressure in the non-processing space S1 to a pressure higher than the normal pressure through the non-processing space exhaust line 521 and the non-processing space high pressure control valve 522.

As illustrated in FIG. 2, the second gas exhaust part 520 may control the non-processing space S1 to a low pressure less than the normal pressure, i.e., a vacuum atmosphere.

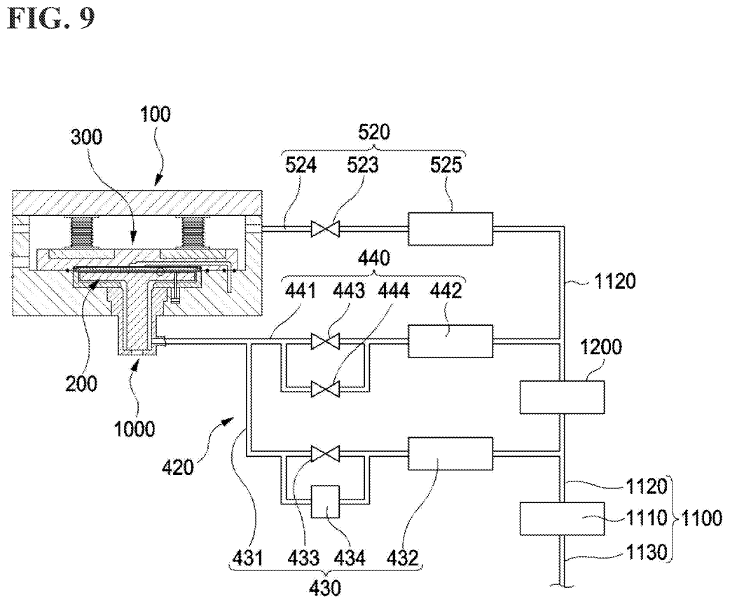

For this, as illustrated in FIG. 9, the second gas exhaust part 520 may include a non-processing space pumping exhaust line 524 installed to allow the gas exhaust hole 180 and the external vacuum pump 1200 to communicate with each other, and a non-processing space pumping control valve 525 installed on the non-processing space pumping exhaust line 524 to control an amount of filling gas flowing from the non-processing space S1 to the external vacuum pump 1200 so that the pressure of the non-processing space S1 is controlled to a pressure lower than the normal pressure.

In addition, as described above, the pressure opening/closing valve 523 installed on the non-processing space pumping exhaust line 524 may be applied in the same manner.

Furthermore, the installation configuration of the non-processing space pumping exhaust line 524 and the non-processing space pumping control valve 525 may also be applied in the same manner as the non-processing space exhaust line 521 and the non-processing space high-pressure control valve 522.

The configuration of the second pressure adjusting part 500 and the first pressure adjusting part 400 for controlling the pressure of the non-processing space S1 may be connected by sharing the same external exhaust device 1100, and for another example, each of the second pressure adjusting part 500 and the first pressure adjusting part 400 may be connected to a separate and independent external exhaust device 1100 to perform the exhaust.

In addition, the configuration of the second pressure adjusting part 500 and the first pressure adjusting part 400 may be connected by sharing the same external exhaust device 1200, and for another example, each of the second pressure adjusting part 500 and the first pressure adjusting part 400 may be connected to a separate and independent external vacuum pump 1200 to perform the pumping.

In the process of changing the pressure of the processing space S2, in which the substrate 1 is seated, from the first pressure higher than the normal pressure to the second pressure, the second pressure adjusting part 500 may be configured to constantly maintain the pressure in the non-processing space S1.

Here, the second pressure adjusting part 500 may maintain the pressure of the non-processing space S1 as vacuum while the substrate processing is performed, and in this process, the pressure of the processing space S2 may be less than or equal to that of the processing space S2.

That is, the second pressure adjusting part 500 may constantly maintains the pressure of the non-processing space S1 at a pressure of about 0.01 Torrs, which is the second pressure, in the substrate processing process, to maintain the pressure so as to be equal to or less than that of the processing space S2. As a result, impurities may be prevented from being introduced from the non-processing space S1 into the processing space S2.

For another example, the second pressure adjusting part 500 may change the pressure of the non-processing space S1, and in this process, the pressure of the non-processing space S1 may have a pressure value less than that of the processing space S2.

In addition, the second pressure adjusting part 500 may adjust the pressure of the non-processing space S1 through only the exhaust without supplying the filling gas to the non-processing space S1 during the substrate processing process.

That is, the second pressure adjusting part 500 may adjust the pressure of the non-processing space S1 through only an operation of the second gas exhaust part 520 without suppling the filling gas according to the second gas supply part 510.

For another example, the second pressure adjusting part 500 may supply the filling gas to the non-processing space S1, and the pressure of the non-processing space S1 may be adjusted together with the exhaust of the second gas exhaust part 520.

Unlike the above, the second pressure adjusting part 500 may include a gas supply hole 170 transferring the filling gas supplied from the outside and a gas exhaust hole 180 exhausting the non-processing space S1 as a gas exhaust hole 180 defined in one side of the process chamber 100, i.e., the chamber body 110, and a gas supply hole 170 defined in the other side.

The controller may have a configuration that controls the pressure adjustment of the processing space S2 and the non-processing space Si through the first pressure adjusting part 400 and the second pressure adjusting part 500.

Particularly, in connection with the process of the substrate processing, the controller may perform the control through the first pressure adjusting part 400 and the second pressure adjusting part 500 of the non-processing space S1 and the processing space S2 in each process.

For example, the controller may supply a purge gas through the first gas supply part 410 and exhaust the purge gas through the second gas exhaust part 520 in a state in which the inner lid part 300 ascends so that the processing space S2 and the non-processing space S1 communicate with each other.

More specifically, to perform cleaning of the processing space S2 in which the substrate processing is performed, the controller may supply the purge gas through the first gas supply part 410 to clean or purge a surrounding of the substrate support 200, in which the substrate processing is performed, in a state in which the inner lid part 300 ascends so that the processing spaced S2 and the non-processing space S1 communicate with each other.

Furthermore, the purge gas may be exhausted through the second gas exhaust part 520 provided on the side surface of the process chamber 100 to induce an upward flow of the purge gas supplied through the first gas supply part 410 to the side surface, thereby inducing internal floating matters to be exhausted to the non-processing space S1 and the outside.

In addition, before ascending of the inner lid part 300, the controller may control the pressure so that the pressures of the processing space S2 and the non-processing space S1 are the same through at least one of the first pressure adjusting part 400 or the second pressure adjusting part 500.

More specifically, the controller may control the pressure so that the pressures of the processing space S2 and the non-processing space S1 are the same through at least one of the first pressure adjusting part 400 or the second pressure adjusting part 500 to prevent the substrate 1 from being changed in position or damaged due to a pressure difference between the non-processing space S1 and the processing space S2 before the substrate processing is performed in a state in which the inner lid part 300 descends to define the sealed processing space S2, and the inner lid part 300 ascends to unload the processed substrate 1.

That is, when the non-processing space S1 and the processing space S2 communicate with each other due to the ascending of the inner lid part 300 while the pressure difference between the non-processing space S1 and the processing space S2 is maintained, in order to prevent the substrate 1 from being affected by the generation of the airflow in one direction due to the pressure difference, the controller may control at least one of the first pressure adjusting part 400 and the second pressure adjusting part 500 so that the pressures of the non-processing space S 1 and the processing space S2 are the same.

The substrate processing apparatus according to the present invention may further include a sealing part 900 including a first sealing member 910 provided on a contact surface between the inner lid part 300 and the process chamber 100 to prevent the process gas from leaking from the processing space S2 to the non-processing space Si and a second sealing part configured to prevent the processing gas from leaking through the gas supply passage 190.

The sealing part 900 may have a configuration provided on at least one of the inner lid part 300 or the bottom surface 120 of the process chamber 100 and may be provided to correspond to a position at which the bottom surface 120 of the processing chamber 100 and the inner lid part 300 are in close contact with each other.

That is, when the edge of the inner lid part 300 is in close contact with the bottom surface 120 to define the sealed processing space S2, the sealing part 900 may be provided along an edge of the bottom surface of the inner lid part 300 so as to be in contact with the bottom surface 120.

Thus, the sealing part 900 may induce the formation of the sealed processing space S2 and prevent a process gas of the processing space S2 from leaking to the outside of the inner space.

For example, the sealing part 900 may include a first sealing member 910 provided along the edge of the bottom surface of the inner lid part 300 and a second sealing member 920 provided at a position spaced a predetermined distance from the first sealing member 910.

Here, each of the first sealing member 910 and the second sealing member 920 may be an O-ring according to the related art, and the first sealing member 910 and the second sealing member 920 may be installed to be spaced a predetermined distance from each other along the edge of the bottom surface of the inner lid part 300.

That is, the first sealing member 910 and the second sealing member 920 may perform double sealing on the processing space S2 to prevent the process gas from leaking from the processing space S2 to the outside.

In addition, the second sealing member 920 may be installed to surround the gas introduction passage 190 or surround the gas supply passage 320 on the bottom surface of the inner lid 310 to prevent the process gas from leaking through the contact surface when the inner lid 310 descends to connect the gas introduction passage 190 to the gas supply passage 320.

The sealing part 900 may be installed by being inserted into an insertion groove provided in the bottom surface 120 and may be in close contact with or separated from the inner lid part 300 according to the vertical movement of the inner lid part 300.

For another example, the sealing part 900 may also be provided on the bottom surface of the inner lid part 300.

The inner lid driving part 600 may be installed to pass through the top surface of the process chamber 100 so as to drive the vertical movement of the inner lid part 300 and may have various configurations.

For example, the inner lid driving part 600 may include a plurality of driving rods 610, each of which one end passes through the top surface of the process chamber 100 and is coupled to the inner lid part 300, and at least one driving source 620 connected to the other end of each of the plurality of driving rods 610 to drive the driving rods 610 vertically.

In addition, the inner lid driving part 600 may further include a fixing support 630 installed on the top surface of the process chamber 100, i.e., the top lid 140 to fix and support the end of the driving rod 610 and a bellows 630 installed to surround the driving rod 610 between the top surface of the process chamber 100 and the inner lid part 300.

The driving rod 610 may have a configuration having one end passing through the top surface of the process chamber 100 so as to be coupled to the inner lid part 300 and the other end coupled to the driving source 620 outside the process chamber 100 to drive the inner lid part 300 vertically through the vertical movement due to the driving source 620.

Here, the driving rod 610 may be provided in plurality, more particularly, two or four to be coupled to the top surface of the inner lid part 300 at a predetermined interval so that the inner lid part 300 moves vertically while being maintained horizontally.

The driving source 620 may have a configuration that vertically drives the driving rod 610 installed and coupled to the fixing support 640 and may have various configurations.

The driving source 620 may be applied to any configuration as long as it is driving method that is disclosed in the related art, for example, various driving methods such as a cylinder method, an electromagnetic driving, screw motor driving, cam driving, and the like may be applied.

The bellows 630 may have a configuration that is installed to surround the driving rod 610 between the top surface of the process chamber 100 and the inner lid part 300 to prevent the gas in the non-processing space S1 from leaking thought the top surface of the process chamber 100.

Here, the bellows 630 may be installed in consideration of the vertical movement of the inner lid part 300.

As described above, when the substrate support 200 is installed in the installation groove 130, a space may be defined between the substrate support 200, more particularly, the substrate support plate 210 and the installation groove 130 to act as a factor that increases in volume of the processing space S2.

To solve this limitation, when the substrate support 200 is installed to be in contact with the installation groove 130, heat supplied through the heater existing in the substrate support 200 may be lost to the process chamber 100 through the bottom surface of the process chamber 100, i.e., the installation groove 130 to cause a heat loss. As a result, it may be difficult to set and maintain the process temperature with respect to the processing space S2, and efficiency may be deteriorated.

To solve this limitation, the filling member 700 according to the present invention may have a configuration that is installed between the substrate support 200 and the bottom surface of the process chamber 100, and may have various configurations.

For example, the filling member 700 may be installed in the installation groove 130, and in the state of being installed in the insulation groove 130, the substrate support plate 210 may be installed at the upper side to minimize a remaining volume between the installation groove 130 and the substrate support plate 210, thereby reducing the volume of the processing space S2.

For this, the filling member 700 may be provided in a shape corresponding to the interspace between the installation groove 130 and the substrate support 200 so that the processing space S2 is minimized.

More specifically, the filling member 700 may have a planar circular shape and may be provided in shape corresponding to the interspace between the installation groove 130, which is defined to have a predetermined depth from the bottom surface 120 with the height difference, and the substrate support plate 210.

For this, the filling member 700 may have a shape of the circular plate provided between the substrate support plate 210 and the installation groove 130 or may have an edge that is provided with an upwardly stepped portion to occupy the interspace between the side surface of the substrate support plate 210 and the installation groove 130 in the shape of the circular plate.

That is, the filling member 700 may be installed to be adjacent to at least one of the side surface or the bottom surface of the substrate support plate 210 and may be spaced apart from the substrate support plate 210 to surround the bottom surface and the side surface of the substrate support plate 210.

Here, to prevent the heat from being lost through the filling member 700, the substrate support 200 may be installed to be spaced apart from the filling member 700, and in more detail, the substrate support 200 may be installed with a degree of a fine gap by which the substrate support 200 is not contact with the filling member 700.

As a result, a predetermined distance may be maintained between the substrate support 200 and the filling member 700, and the gap may act as an exhaust passage, and thus, exhaust with respect to the processing space S2 may be performed.

More specifically, the substrate support 200 and the filling member 700 may be installed to be spaced apart from each other to define the exhaust passage. Here, the exhaust passage may communicate with the bottom of the installation groove 130, through which the substrate support shaft 220 passes, to exhaust the process gas within the processing space S2 to the outside.

The filling member 700 may be made of at least one of quartz, ceramic, or SUS.

In addition, the filling member 700 may not only simply occupy the space between the installation groove 130 and the substrate support 200 to minimize the volume of the processing space S2, but also minimize the loss of the heat transferred to the substrate 1 through the substrate support 200 through thermal insulation and furthermore reflect the heat that is lost to the processing space S2 through thermal reflection.

That is, the filling member 700 may not only minimize the volume of the processing space S2, but also insulate for preventing the heat from being lost through the substrate support 200 to the bottom surface 120 of the process chamber 100, furthermore, perform a reflection function to be improved in thermal efficiency through the reflection of heat.

In addition, to improve the reflection effect of the heat emitted through the substrate support 200 to the processing space S2, a reflection part provided on the surface of the substrate support 200 may be additionally provided.

That is, the filling member 700 may include an insulating part for blocking heat from the processing space S2 to the outside and a reflection part provided on a surface of the insulating part to reflect heat.

Here, the reflection part may be coated, adhered, or applied on the surface of the heat insulating part to provide a reflection layer and may reflect heat lost from the processing space S2 through the process chamber 100 so as to be transferred again to the processing space S2.

In addition, the filling member 700 may further include a first through-hole having a size corresponding to a center so that the foregoing substrate support shaft 220 is installed and a plurality of second through-holes passing through the plurality of substrate support pins 810 to move vertically.

The substrate support pin part 800 may have a configuration that supports the substrate 1 loaded into or unloaded from the process chamber 100 and is seated on the substrate support 200 and may have various configurations.

For example, the substrate support pin part 800 may include a plurality of substrate support pins 810 passing through the filling member 700 and the substrate support 200 to move vertically, thereby supporting the substrate 1, an annular substrate support ring 820 on which the plurality of substrate support pines 810 are installed, and a substrate support pin driving part 830 that drive the plurality of substrate support pins 810 vertically.

The plurality of substrate support pins 810 may have a configuration that is provided in plurality on the substrate support ring 820 to pass through the filling member 700 and the substrate support 200 so as to move vertically, thereby supporting the substrate 1 and may have various configurations.

Here, the plurality of substrate support pins 810 may be provided in at least three and may be installed to be spaced apart from each other on the substrate support ring 820. Also, the plurality of substrate support pins 810 may ascend to be exposed from the substrate support 200, thereby supporting the substrate 1 that is loaded or may descend to be disposed inside the substrate support 200, thereby seating the substrate 1 on the substrate support 200.

The substrate support ring 820 may have an annular configuration on which the plurality of substrate support pins 810 are installed so that the plurality of substrate support pins 810 move vertically at the same time through the vertical movement.

Particularly, the substrate support ring 820 may be installed in a support pin installation groove 160 defined in the bottom surface of the process chamber 100, that is, the installation groove 130 to move vertically by a substrate support pin driving part 830.

The substrate support pin driving part 830 may have a configuration that is installed outside the process chamber 100 to drive the substrate support ring 820 vertically, and may have various configurations.

For example, the substrate support pin driving part 830 may include a substrate support pin rod 831 that has one end connected to the bottom surface of the substrate support ring 820 and the other end connected to a substrate support pin driving source 833 to move vertically according to driving force of the substrate support pin driving source 833, and a substrate support guide 832 configured to guide linear movement of the substrate support pin rod 831, and a substrate support pin driving source 833 configured to drive the substrate support pin rod 831.

In addition, the substrate support pin part 800 may further include a substrate support bellows 840 that surrounds the substrate support pin rod 831 and is installed between the bottom surface of the process chamber 100 and the substrate support pin driving source 833.

The manifold part 1000 may have a configuration that is installed on the bottom surface of the process chamber 100 so as to communicate with the processing space S2 so that at least one processing space exhaust port is provided to allow the high-pressure controller 430 and the pumping controller 440 to communicate with each other and may have various configurations.

For example, as illustrated in FIG. 3, the manifold part 1000 may include a manifold 1010 installed on the bottom surface of the process chamber 100 to communicate with the processing space S2 and a processing space exhaust port provided on the manifold 1010 and coupled to at least one of the above-described high-pressure controller 430 and the above-described pumping controller 440.

Here, the manifold 1010 may be installed on the bottom surface of the process chamber 100 to communicate with the processing space S2 and thus may be used as an mediate for the exhaust of the processing space S2, the high-pressure adjusting part 430, and the pumping controller 440.

In addition, the manifold 1010 may have a lower through-hole 1011 so that various conductors connected to a heater installed in the substrate support plate through the above-described substrate support shaft 220 are installed to pass therethrough.

The processing space exhaust port may include a high-pressure exhaust port 1020 provided on the manifold 1010 and connected to the high-pressure controller 430 as described above and a pumping exhaust port 1030 connected to the pumping controller 440.

For another example, the processing space exhaust port may be provided as a single port on the manifold 1010 to communicate with all the high-pressure exhaust port 1020 and the pumping exhaust port 1030 in a state of being coupled to the high-pressure exhaust port 1020 and the pumping exhaust port 1030.

As illustrated in FIG. 6, the external exhaust device 1100 may include a harmful material removing part 1110 for removing harmful materials discharged from the processing space S2 and the non-processing space S1 and an external exhaust line 1120 configured to connect the harmful material removing part 1110, the high-pressure controller 430, the pumping controller 440, and the second gas exhaust part 520 to each other.

In addition, the external exhaust device 1100 may further include an exhaust line 1130 for exhausting an exhaust gas from which the harmful materials are removed to the outside at the rear end of the harmful material removing part 1110.

In this case, the above-described external vacuum pump 1200 may be installed at a position connected to the second gas exhaust part 520 and the pumping controller 440 at a front end of the harmful material removing part 1110 to pump each of the non-processing space S1 and the processing space S2.

Here, as illustrated in FIG. 6, the high-pressure adjusting part 430 may be connected to the external exhaust line 1120 at the rear end of the external vacuum pump 1200 to protect the external vacuum pump 1200, and thus the harmful materials may be transferred to the harmful material removing part 1110.

The substrate processing apparatus according to the present invention may minimize the volume of the processing space in which the substrate inside the chamber is processed to improve the pressure change rate in the wide pressure range, and thus, the pressure may be changed at the high pressure rate of about 1 Bar/s from the low pressure of about 0.01 Torrs to the high pressure of about 5 Bars.

In addition, the substrate processing apparatus according to the present invention may have the advantage of reducing the dead volume and minimizing the volume by omitting the installation of the separate gas supply part at the position adjacent to the substrate support as the process gas is injected upward from the substrate support.

In addition, the substrate processing apparatus according to the present invention may have the advantage in that, as the process gas is injected toward the substrate from the upper side of the substrate support, the process gas may be smoothly supplied toward the edge of the substrate as well as the central side of the substrate, to realize the uniform substrate processing.

In addition, the substrate processing apparatus according to the present invention may have the advantage in that, as the kind of buffer space of the non-processing space is defined between the processing space and the outer space of the process chamber, the harmful substances such as the process gas of the processing space is prevented from leaking to the outside of the process chamber, thereby improving the safety in the substrate processing.

In addition, the substrate processing apparatus according to the present invention may have the advantage in that the non-processing space is defined between the processing space and the outer space of the process chamber, and the pressure of the non-processing space is controlled to prevent the impurities from being introduced into the processing space, thereby improving the quality in the substrate processing.

In addition, the substrate processing apparatus according to the present invention has advantages in that the exhaust of the processing space is dualized according to the pressure to improve the exhaust efficiency of the processing space, thereby improving the durability of the components of the apparatus.

Although the above description merely corresponds to some exemplary embodiments that may be implemented by the present invention, as well known, the scope of the present invention should not be interpreted as being limited to the above-described embodiments, and all technical spirits having the same basis as that of the above-described technical spirit of the present invention are included in the scope of the present invention.

What is claimed is:

1. A substrate processing apparatus comprising:
a process chamber comprising a chamber body which has an opened upper portion, in which an installation groove is defined at a central side of a bottom surface thereof, and which comprises a gate for loading/unloading a substrate is disposed at one side thereof and a top lid coupled to the upper portion of the chamber body to define an inner space;
a substrate support installed to be inserted into the installation groove of the chamber body and having a top surface on which the substrate is seated;
an inner lid part which is installed to be vertically movable in the inner space and of which a portion is in close contact with the bottom surface adjacent to the installation groove through descending to divide the inner space into a sealed processing space, in which the substrate support is disposed, and other non-processing space;
a first pressure adjusting part communicating with the processing space to adjust a pressure of the processing space;
a second pressure adjusting part communicating with the non-processing space to adjust a pressure of the non-processing space independently of the processing space; and
a controller configured to control the pressure adjusting of the processing space and the non-processing space through the first pressure adjusting part and the second pressure adjusting part.

2. The substrate processing apparatus of claim 1, wherein the first pressure adjusting part comprises:
a first gas supply part configured to supply the process gas to the processing space; and
a first gas exhaust part configured to exhaust the processing space, and
the second pressure adjusting part comprises:
a second gas exhaust part connected to a gas exhaust hole defined in one surface of the process chamber to exhaust the non-processing space; and
a second gas supply part connected to a gas supply hole defined in the other surface of the process chamber to communicate with the non-processing space so as to supply a filling gas to the non-processing space.

3. The substrate processing apparatus of claim 2, wherein the controller supplies a purge gas through the first gas supply part and exhaust the purge gas through the second gas exhaust part in a state in which the inner lid part ascends to allow the processing space and the non-processing space to communicate with each other.

4. The substrate processing apparatus of claim 1, wherein the controller controls, before the inner lid part ascends, at least one of the first pressure adjusting part or the second pressure adjusting part so that the pressures of the processing space and the non-processing space are the same.

5. The substrate processing apparatus of claim I, wherein the controller changes the pressure of the processing space, in which the substrate is seated to perform the substrate processing, between a first pressure higher than a normal pressure and a second pressure lower than the normal pressure through the first pressure adjusting part.

6. The substrate processing apparatus of claim 1, wherein the controller maintains the pressure of the non-processing space to a vacuum pressure while the substrate processing is performed through the second pressure adjusting part.

7. The substrate processing apparatus of claim 6, wherein the controller maintains the pressure of the non-processing space to a pressure lower than that of the processing space while the substrate processing is performed through the second pressure adjusting part.

8. The substrate processing apparatus of claim 5, wherein the controller sequentially and repeatedly changes the pressure of the processing space several times from the first pressure to the second pressure and then to first pressure through the first pressure adjusting part so as to perform the substrate processing.

9. The substrate processing apparatus of claim 1, wherein the first pressure adjusting part comprises a first gas supply part installed to communicate with the processing space so as to supply the process gas to the processing space and installed adjacent to an edge of the substrate support.

10. The substrate processing apparatus of claim 1, wherein the first pressure adjusting part comprises a first gas supply part installed to communicate with the processing space so as to supply the process gas to the processing space, and
the first gas supply part comprises:
a gas injection part installed on an edge of the installation groove to inject the process gas; and
a gas supply passage provided to pass through a bottom surface of the process chamber so as to supply the process gas to the gas injection part from the outside.

11. The substrate processing apparatus of claim 1, wherein the inner lid part comprises:
an inner lid that moves vertically in the inner space; and
a gas supply passage provided to communicate with the processing space inside the inner lid.

12. The substrate processing apparatus of claim 11, wherein the first pressure adjusting part comprises a first gas supply part disposed below the inner lid part to inject the process gas transferred through the gas supply passage to the processing space.

13. The substrate processing apparatus of claim 12, wherein the first gas supply part comprises an injection plate disposed below the inner lid part and provided with a plurality of injection holes.

14. The substrate processing apparatus of claim 13, wherein the first gas supply part further comprises:
an injection plate support configured to support an edge of the injection plate and coupled to a bottom surface of the inner lid part; and
a plurality of coupling member passing through the injection plate support and coupled to the inner lid part.

15. The substrate processing apparatus of claim 12, wherein the inner lid comprises an insertion installation groove into which at least a portion of the gas supply part is inserted and installed in a bottom surface thereof, and
the first gas supply part is provided so that a bottom surface thereof provides a plane with the bottom surface of the inner lid in a state of being inserted and installed in the insertion installation groove.

16. The substrate processing apparatus of claim 11, wherein the process chamber comprises a gas introduction passage provided to transfer the process gas introduced from the outside to a bottom surface that is in contact with the inner lid part, and
the inner lid part descends to be in close contact with the bottom surface so as to connect the gas introduction passage to the gas supply passage, thereby supply the process gas to the gas supply passage.

17. The substrate processing apparatus of claim 1, wherein the first pressure adjusting part comprises:
a high-pressure adjusting part configured to control the pressure of the processing space to a pressure higher than the normal pressure through the exhaust of the processing space and;
a pumping controller configured to control the pressure of the processing space to a pressure lower than the normal pressure through pumping of the processing space.

18. The substrate processing apparatus of claim 17, wherein the high-pressure controller comprises:
a high-pressure exhaust line installed to allow the processing space and the external exhaust device to communicate with each other; and
a high-pressure control valve installed on the high-pressure exhaust line to control an amount of process gas flowing from the processing space to the external exhaust device so that the pressure of the processing space is controlled to a pressure higher than the normal pressure, and
the pumping controller comprises a pumping exhaust line installed to allow the processing space and an external vacuum pump to communicate with each other, and
a pumping control valve installed on the pumping exhaust line to control an amount of process gas flowing from the processing space to the external vacuum pump so that the pressure of the processing space is controlled to a pressure lower than the normal pressure.

19. The substrate processing apparatus of claim 2, wherein the second gas exhaust part comprises:
a non-processing space exhaust line installed to allow the gas exhaust hole and the external exhaust device to communicate with each other; and
a non-processing space high-pressure control valve installed on the non-processing space exhaust line to control an amount of filling gas flowing from the non-processing space to the external exhaust device so that the pressure of the non-processing space is controlled to a pressure higher than the normal pressure.

20. The substrate processing apparatus of claim 2, wherein the second gas exhaust part comprises:
a non-processing space pumping exhaust line installed to allow the gas exhaust hole and the external vacuum pump to communicate with each other; and
a non-processing space pumping control valve installed on the non-processing space pumping exhaust line to control an amount of filling gas flowing from the non-processing space to the external vacuum pump so that the pressure of the non-processing space is controlled to a pressure lower than the normal pressure.
